(19) United States
(12) Patent Application Publication
(10) Pub. No.: US 2025/0054918 A1
(43) Pub. Date: Feb. 13, 2025

(54) POWER MODULE BRIDGE AND ITS MANUFACTURING PROCESS

(71) Applicant: Robert Bosch GmbH, Stuttgart (DE)

(72) Inventor: Irfan Aydogmus, Nuertingen (DE)

(21) Appl. No.: 18/783,515

(22) Filed: Jul. 25, 2024

(30) Foreign Application Priority Data
Aug. 11, 2023 (DE) 10 2023 207 744.2

(51) Int. Cl. H01L 25/07; H01L 23/00

(52) U.S. Cl. CPC H01L 25/072; H01L 23/562; H01L 24/45; H01L 24/48; H01L 2224/45124; H01L 2224/45147; H01L 2224/48137; H01L 2924/182; H01L 2924/186

(57) ABSTRACT

A power module bridge. The power module includes: one or more power modules, each including: a circuit carrier(s) which includes at least three layers of material, a middle circuit carrier layer includes an insulating material, and first and second outer circuit carrier layers include an electrically conductive material, the outer layers being configured as one or more conductor structures, one or more bonding wires which include a connection from semiconductor switch to semiconductor switch and semiconductor switch to press-in pins, and one or more semiconductor switches, each semiconductor switch including first and second semiconductor layers; a cooling surface, a frame, filled with a gel, with lateral boundaries and an upwardly and/or downwardly exposed region; one or more connecting elements; and one or more press-in pins; wherein circuit carrier(s), first semiconductor layer(s} and second semiconductor layer(s) are connected to one another via a sintered connection.

### CROSS REFERENCE

The present application claims the benefit under 35 U.S.C. § 119 of German Patent Application No. DE 10 2023 207 744.2 filed on Aug. 11, 2023, which is expressly incorporated herein by reference in its entirety.

### FIELD

The present invention relates to a power module bridge, in particular a power module bridge such as a power module B6 bridge for converting a direct current into an alternating current. The present invention also relates to one or more power modules without a molded body and without a flexible printed circuit board (flex PCB) and a frame with overmolded press-in pins as well as their integration into a power module bridge and gelling the one or more power modules inside the power module bridge.

### BACKGROUND INFORMATION

In the related art, power modules that are installed in a power module bridge, for example, are additionally molded. During molding, the power module is embedded in a solid housing, for example made of plastic (molding compound). The purpose of the molding compound is to encase and protect the interior of the power module. However, these encasements of the power module with molding compound are not particularly crack-resistant. A power module moreover often includes a flexible printed circuit board that serves as a connection between the power module and a gate circuit board.

German Patent Application No. DE 10 2021 202 336 A1 relates to a circuit arrangement with a circuit carrier on which electrical and/or electronic components of a circuit are disposed, and with an at least partially flexible connecting element which is connected to the circuit carrier at least in one contact region and is configured to form an electrical contact-connection with the circuit, wherein the connecting element is a flexible printed circuit board film comprising a plurality of layers, which is disposed in the contact region with a first section at least nearly parallel to the plane of the circuit carrier and is connected to the circuit carrier, wherein the first section is adjoined on the side facing away from the circuit carrier by a flexible second section which projects from the plane of the circuit carrier and in which at least one longitudinal slot parallel to a longitudinal direction of the second section is formed.

German Patent Application No. DE 11 2017 004 390 T5 relates to a power module that includes the following: an insulating substrate with a front side on which a power semiconductor is mounted; a base plate which is connected to a rear side of the insulating substrate; a housing which is mounted on the base plate and encloses the insulating substrate; a lid which is mounted on the housing and defines a sealed region; a silicone gel which serves as a filling element and fills the entire sealed region and has internal stress that acts as compressive stress; a cover, which is attached to the housing and forms a sealed region; and a silicone gel which serves as a filler, fills the entire sealing region and has residual stress that acts as compressive stress.

### SUMMARY

According to the present invention, a power module bridge, such as a power module B2 or a power module B6 bridge according to a first aspect is disclosed, which includes:
one or more power modules, wherein the one or more power modules comprise:
   i. one or more circuit carriers which include at least three layers of material, wherein a middle circuit carrier layer includes an insulating material, a first outer circuit carrier layer and a second outer circuit carrier layer include an electrically conductive material, wherein the outer layers are configured as one or more conductor structures,
   ii. one or more bonding wires, wherein the bonding wires include a connection from semiconductor switch to semiconductor switch and semiconductor switch to press-in pins, and
   iii. one or more semiconductor switches, wherein a semiconductor switch includes a first semiconductor layer and a second semiconductor layer,
a cooling surface,
a frame with lateral boundaries and with an upwardly and/or downwardly exposed region, wherein a volume enclosed by the frame is filled with a gel,
one or more connecting elements, and
one or more press-in pins,

wherein one or more circuit carriers, one or more first semiconductor layers and one or more second semiconductor layers are connected to one another via a sintered connection.

The solution according to the present invention presents a power module bridge. A power module bridge is an electronic circuit in which power electronics, such as power modules, are used. The power module bridges are used in a variety of applications such as engine controls, power converter circuits, switched-mode power supplies and power converters. The solution according to the present invention is particularly suitable for power converters within an electric vehicle, for example. Here, a power converter converts direct current (DC) to alternating current (AC).

A circuit carrier is a component of the power module. A circuit carrier can, for example, include a plurality of layers of material, in which case the outer layers contain an electrically conductive layer, for instance, and the inner layer contain an electrically non-conductive material. A conductive layer can be used to electrically connect various power electronic components, for example. Effective thermal management of the power electronics can moreover be made possible by integrating an electrically non-conductive layer, for instance. The integration of conductive and non-conductive layers can, for example, create heat dissipation paths to dissipate heat from power components. The outer layers of a circuit carrier can be configured as conductor structures, for example, in which case the number and shape of a conductor structure can vary depending on the power module. A power structure includes a conductive material that is applied to an insulating circuit carrier and serves to enable the flow of electrical current between the components and ensure efficient energy transfer.

A semiconductor switch within the meaning of the present invention includes a first semiconductor layer and a second semiconductor layer.

Another component of a power module bridge provided according to an example embodiment of the present invention is a cooling surface. A cooling surface is used to dissipate excess heat produced during operation of the power module or plurality of power modules. A cooling surface within the meaning of the present invention also fulfills a function for heat dissipation, heat distribution, temperature control, long-term stability and protection against thermal failures. A cooling surface can be made of metals with high thermal conductivity, such as aluminum or copper, for instance, in order to dissipate heat from one or more heat-producing power modules.

A frame is another component of a power module bridge according to an example embodiment of the present invention. According to an example embodiment of the present invention, a frame includes overmolded press-in pins. Press-in pins are specialized contact pins used to establish a permanent electronic connection between an electronic component and a printed circuit board, for example a power module. The use of press-in pins makes it possible to avoid conventional solder connections, for instance. Using press-in pins to establish a connection makes it possible to achieve a stable and reliable connection of the electronic components.

The solution according to the present invention creates a particularly advantageous structure of the power module bridge. The power modules installed inside the power module bridge are not encased with a molding compound as in other possible state-of-the-art structures; the power module has instead been covered with a gel without such an additional encasement.

In a further development of the power module bridge according to the present invention, it is provided that the one or more power modules are positioned inside a frame.

In another further development of the power module bridge according to the present invention, at least one first outer circuit carrier layer includes one or more conductor structures, wherein the conductor structures are configured such that they have a symmetrical arrangement and/or shape that is mirrored with respect to the centerline of the circuit carrier layer.

According to an example embodiment of the present invention, a first outer circuit carrier layer can be configured as a symmetrical connection on a T plus path and a symmetrical connection on a phase path, for example. A T plus path is a conductor structure that has a T-shaped structure, for instance, and is responsible for splitting or combining an electrical current between different branches within a power module, for example. A phase path is a structure consisting of a conductor structure and/or conductor structures that includes all relevant components and connections, for example to accurately analyze, control or maintain a phase relationship between input currents and output currents. A symmetrical connection is a symmetrical current path, for example.

A symmetrical current path is, for instance, characterized by the fact that an electrical current is evenly distributed across the various conductor structures of a power module and/or power components, such as semiconductor switches, on a circuit carrier.

A symmetrical current path can be achieved by a symmetrical arrangement of a conductor structure, for example, wherein the conductor structures of the same length pair are arranged in parallel and at a defined mutual distance and have identical electrical properties and arrangement of the semiconductor switches.

A symmetrical arrangement of one or more conductor structures can, for example, achieve a uniform load on the semiconductor switches which are, for instance, sintered onto the conductor structures. Moreover, in the event of a short circuit, the energy absorbed can be absorbed evenly by all of the semiconductor switches, as a result of which a vehicle, for example, can be safely disconnected from a current path in order to protect other components of the vehicle.

In an advantageous further development of the power module bridge according to an example embodiment of the present invention, a power module bridge is provided, wherein the bonding wires that establish a connection from semiconductor switch to semiconductor switch comprise a copper material.

In a further development of the power module bridge according to the present invention, it is provided that bonding wires which establish a connection from semiconductor switches to the press-in pins are made of an aluminum material.

In a further development of the power module bridge provided according to the present invention, a power module bridge is proposed, in which a frame has a variable frame height, wherein a variable frame height is 12 mm, preferably 2 to 7 mm, particularly preferably 4 to 5 mm.

According to an example embodiment of the present invention, a variable frame height is provided, wherein the frame height is based on the height of the power modules installed in the frame, because the frame height forms the enclosed volume for filling the gel. Following the solution according to an example embodiment of the present invention, the frame height is higher than the power module and components, such as bonding wires and semiconductor circuits, connected to the power module.

In a further development of the power module bridge according to the present invention, a power module bridge is provided, wherein the volume enclosed by the frame is filled with a gel such that one or more power modules are completely covered with the gel.

An enclosed volume of a frame refers to the area of the bounding structures of the frame. It includes the space bounded by the outer dimensions of the frame, including the surfaces of the power modules, the connecting elements, the bonding wires and other electronic components of the power modules. An enclosed volume includes at least one open side.

In a further development of the power module bridge according to the present invention, a power module bridge is provided, in which the gel is a silicone gel.

A silicone gel is a semi-solid material comprising a silicone polymer network suspended in a liquid or viscous medium. In the context of the use of a power module bridge according to the present invention, the silicone gel exhibits excellent temperature resistance; it tolerates thermal stresses at elevated temperatures very well without compromising structural strength or deforming. Among other things, unlike molding compound, it exhibits high elasticity and flexibility and is therefore able to absorb and distribute thermal stresses without tearing or cracking. A silicone gel also has a lower coefficient of thermal conductivity, which improves the insulation and limitation of local temperature differences.

According to an example embodiment of the present invention, a method for manufacturing a power module bridge including one or more power modules, a cooling surface, a frame, overmolded press-in pins, a gel, and one or more connecting elements according to one of the preceding configurations of the power module bridge according to the present invention is provided, wherein the method comprises the following steps:
I. providing one or more power modules,
II. attaching the one or more power modules to the cooling surface,
III. applying a frame including press-in pins to the cooling surface around the one or more power modules,
IV. connecting the one or more semiconductor switches to the one or more press-in pins,
V. mounting the one or more connecting elements on the one or more power modules, wherein the one or more connecting elements are mounted such that each connecting element is secured via the frame and/or to the frame, and
VI. filling the enclosed region of the frame with a gel.

The method according to the present invention makes it possible to integrate the power module bridge into various embodiments, such as electric vehicles. The method furthermore achieves a particularly advantageous structure of a power module bridge, in which the power module bridge is designed in such a way that thermomechanical stress on the components of the power module bridge is reduced by not encasing a power module with molding compound and by surrounding the electronic components inside a frame with gel. This reduces the occurrence of material fatigue and/or crack formation, for example, which leads to a longer service life of the power module bridge. The occurring temperature differences can also be reduced by the targeted use of cooling measures, for example, which results in an improvement of the structural integrity and the service life.

The method furthermore enables a particularly advantageous structure of a power module bridge, in which the power module bridge is designed in such a way that mechanical stability is achieved without a flexible printed circuit board of a power module. Flexible printed circuit boards are more susceptible to mechanical stress, for instance, and can become loose or damaged over time. Moreover, higher currents can be transmitted via press-in pins than via flexible printed circuit boards. Press-in pins can also be mounted easily and cost-efficiently, whereas flexible printed circuit boards are rather characterized by disadvantageous and complex manufacturing processes. In addition, press-in pins provide a long-lasting and reliable electrical connection compared to flexible printed circuit boards. Compared to flexible printed circuit boards, in which wear can occur as a result of the flexibility of the assemblies, fewer failures occur as a result of temperature changes or repeated movements.

The method according to the present invention is particularly well-suited for efficient heat dissipation, for example, because a gel mass exhibits thermal properties that enable efficient heat dissipation from the encapsulated components. This makes it possible to optimally maintain the operating temperature of a power module bridge, for example. The use of a gel also provides an effective protective layer for the encased power module components against harmful environmental influences such as moisture, dust, dirt or chemical substances. The gel mass can furthermore have a shock and vibration damping effect by acting as a padding and protecting the encased power module components from mechanical stresses. This is particularly advantageous in applications in which electronic components are subjected to vibrations or shocks, such as in the automotive industry. Compared to a rigid encasement material, a gel mass also provides greater flexibility and adaptability to the shape and size of the encased power module components. Moreover, due to the lower material requirements and the less complex processing steps, it is more cost-effective to use a gel mass instead of a rigid encasement.

In an advantageous further development of the method according to the present invention for manufacturing a power module bridge, it is provided that the frame is attached to a cooling surface by gluing or soldering.

In another advantageous further development of the method according to the present invention for manufacturing a power module bridge, a provision of the one or more power modules is proposed, wherein the provision includes producing a power module, wherein a producing at least comprises the following steps:
I. providing a circuit carrier according to the present invention,
II. applying the one or more first semiconductor layers to the circuit carrier, wherein applying includes bonding by sintering;
III. applying the one or more second semiconductor layers to the first semiconductor layer, wherein applying includes bonding by sintering, and
IV. producing a connection between the semiconductor switches by means of bonding wires.

In a further advantageous further development of the method according to the present invention for manufacturing a power module bridge, it is proposed that the frame is attached to a cooling surface by gluing or soldering.

In a further advantageous further development of the method according to the present invention for manufacturing a power module bridge, it is provided that a signal connection is made via press-in pins.

The provided signal connection is a connection technology in which metal pins, also referred to as press-in pins, are inserted into suitable openings in the components to be connected, such as a gate, a source and a temperature sensor.

Pressing in the press-in pins produces a mechanically solid plug connection between the individual components. This also creates an interference-free and reliable electrical connection.

According to the present invention, a use for manufacturing a power module bridge in a vehicle according to a third aspect is disclosed, wherein the power module bridge is used to convert current from direct current to alternating current.

The solution according to the present invention advantageously includes the use of press-in pins. With the help of press-in pins, it is possible to implement a quick and precise connection and disassembly between electronic components and a power module.

The solution according to the present invention also includes a simple method that enables integration into existing power module bridges without interface modification, wherein the necessary molding and application of the flexible printed circuit board is eliminated. In addition, the solution according to the present invention does not require a connection board (DCB), which ensures cost savings. Eliminating the need for encapsulation (molds) and the use of gel to protect the power modules in a frame minimizes mechanical and thermal stresses on the power electronics of the power module and prevents the occurrence of cracks or crack formation.

A further advantage of the solution according to the present invention is that, in contrast to the use of a flexible printed circuit board, the press-in pins represent a more robust mechanical connection. This achieves a firm and permanent anchoring between the power electronic components to be connected, which can withstand mechanical stresses, such as vibrations, shocks and/or temperature variations. A solution with extensive use of press-in pins also achieves a high level of resistance, which ensures long-term mechanical stability and durability. Moreover, a lower thermal load is exerted on the bridge of the power module because the press-in technology does not require soldering, for example, which reduces the risk of damage or deformation of the components due to the effect of heat during the joining process to a minimum.

A further advantage of the solution according to the present invention is high performance as a result of the use of press-in pins. Compared to conventional methods, such as solder connections, this is characterized by a larger contact surface.

### BRIEF DESCRIPTION OF THE DRAWINGS

Example embodiments of the present invention are explained in more detail with reference to the figures and the following description.

FIG. 1 shows a schematic illustration of a circuit carrier with a first semiconductor layer, according to an example embodiment of the present invention.

FIG. 2 shows a schematic illustration of a circuit carrier with a first semiconductor layer and a second semiconductor layer, according to an example embodiment of the present invention.

FIG. 3 shows a schematic illustration of a circuit carrier with a semiconductor switch and bonding wires, according to an example embodiment of the present invention.

FIG. 4 shows a schematic plan view onto a cooling surface with a plurality of power modules, according to an example embodiment of the present invention.

FIG. 5 shows a schematic illustration of a power module bridge, according to an example embodiment of the present invention.

FIG. 6 shows a schematic illustration of a power module bridge with connecting elements, according to an example embodiment of the present invention.

FIG. 7 shows a schematic illustration of a method for manufacturing a power module bridge, according to an example embodiment of the present invention.

### DETAILED DESCRIPTION OF EXAMPLE EMBODIMENTS

In the following description of the embodiments of the present invention, identical or similar elements are denoted by identical reference signs, wherein a repeated description of these elements is omitted in individual cases. The figures show the subject matter of the present invention only schematically.

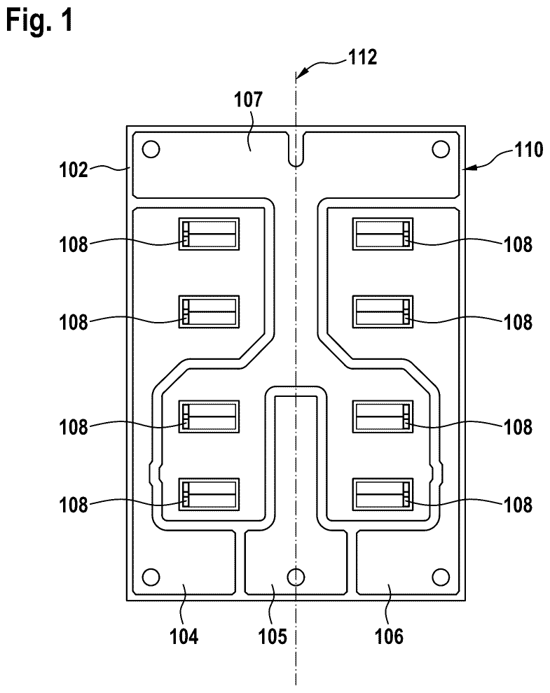

In the schematic illustration according to FIG. 1, the embodiment example includes a circuit carrier 102 according to the present invention which includes a first outer circuit carrier layer 110. A circuit carrier 102 according to FIG. 1 includes a first conductor structure 104, a second conductor structure 105, a third conductor structure 106 and a fourth conductor structure 107, wherein all of the conductor structures 104, 105, 106 and 107 have a conductor shape. FIG. 1 also shows eight first semiconductor layers 108. Two first semiconductor layers 108 are shown on a first conductor structure 104 and two first semiconductor layers 108 are shown on the third conductor structure 106. Four first semiconductor layers 108 on a fourth conductor structure 107 are shown as well. FIG. 1 also shows a centerline 112, which represents a division of a circuit carrier 102 in the middle layer or functions as an axis of symmetry of a circuit carrier 102 and a first outer circuit carrier layer 110.

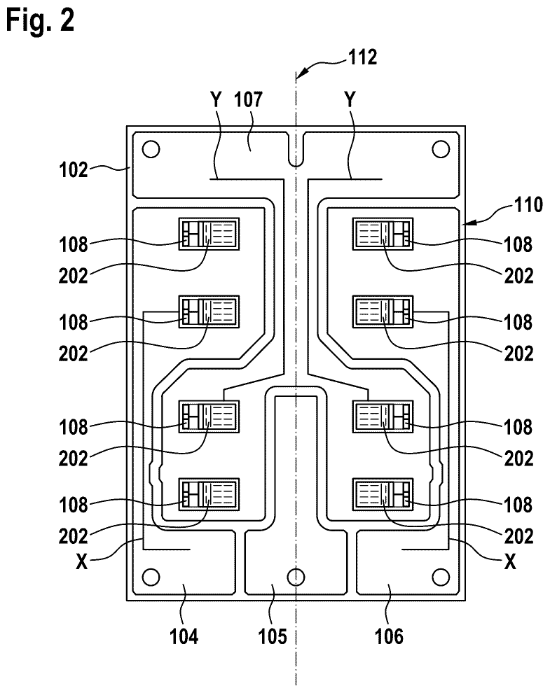

In the schematic illustration according to FIG. 2, the embodiment example of a circuit carrier 102 according to the present invention includes a first outer circuit carrier layer 110. A circuit carrier 102 according to FIG. 1 includes a first conductor structure 104, a second conductor structure 105, a third conductor structure 106 and a fourth conductor structure 107, wherein all of the conductor structures 104, 105, 106 and 107 have a conductor shape. FIG. 2 also shows eight first semiconductor layers 108 and eight second semiconductor layers 202. Two first semiconductor layers 108 and two second semiconductor layers 202 are shown on a first conductor structure 104 and two first semiconductor layers 108 and two second semiconductor layers 202 are shown on the third conductor structure 106. Another four first semiconductor layers 108 and four second semiconductor layers 202 are shown on a fourth conductor structure 107. FIG. 2 also shows a centerline 112, which represents a division of a circuit carrier 102 in the middle layer or functions as an axis of symmetry of a circuit carrier 102 and a first outer circuit carrier layer 110. FIG. 2 further shows two paths X, Y, wherein a path X corresponds to a symmetrical connection on a T plus path and a path Y corresponds to a symmetrical connection on a phase path.

A symmetrical connection corresponds to a symmetrical current path, for example, which results in even loading of semiconductor switches, such as chips.

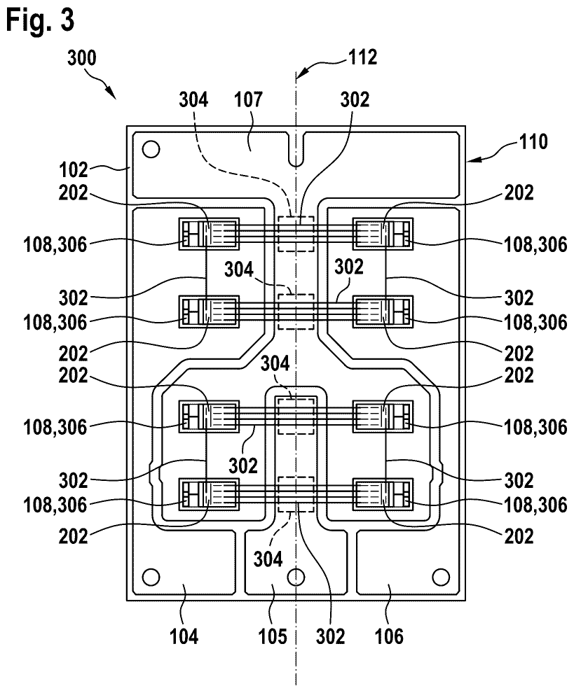

In the schematic illustration according to FIG. 3, the embodiment example of a power module 300 according to the present invention includes a first outer circuit carrier layer 110. A power module 300 according to FIG. 3 includes a circuit carrier 102, a first conductor structure 104, a second conductor structure 105, a third conductor structure 106 and a fourth conductor structure 107, wherein all of the conductor structures 104, 105, 106 and 107 have a conductor shape. FIG. 2 also shows eight first semiconductor layers 108 and eight second semiconductor layers 202. Two first semiconductor layers 108 and two second semiconductor layers 202 are shown on a first conductor structure 104 and two first semiconductor layers 108 and two second semiconductor layers 202 are shown on the third conductor structure 106. Another four first semiconductor layers 108 and four second semiconductor layers 202 are shown on a fourth conductor structure 107. FIG. 3 also includes a connection of the semiconductor switches 306 by means of bonding wires 302. The semiconductor switches 306 of the first conductor structure 104 and the third conductor structure 106 are respectively connected to one another and to the fourth conductor structure 107 in a region 304 by four bonding wires 302. The semiconductor switches 306 located within the same first conductor structure 104 and the same third conductor structure 106 are respectively connected to one another by a bonding wire 302. The semiconductor switches 306 on the fourth conductor structure 107 are respectively connected to one another and to the second conductor structure 105 in a region 304 by four bonding wires 302, and adjacent semiconductor switches 306 on the fourth conductor structure 107 are connected to one another by a bonding wire 302. FIG. 3 also shows a centerline 112, which represents a division of a circuit carrier 102 in the middle layer or functions as an axis of symmetry of a circuit carrier 102 and a first outer circuit carrier layer 110.

The bonding wires comprise a material containing copper, for example, to ensure efficient heat dissipation within a power module 300 between semiconductor switches 306. The bonding wires 302 can be attached to semiconductor switches 306 by ball wedge bonding, for example, in which case a bonding wire 302 is melted into a ball at one end by high current pulses and attached to a semiconductor switch 306.

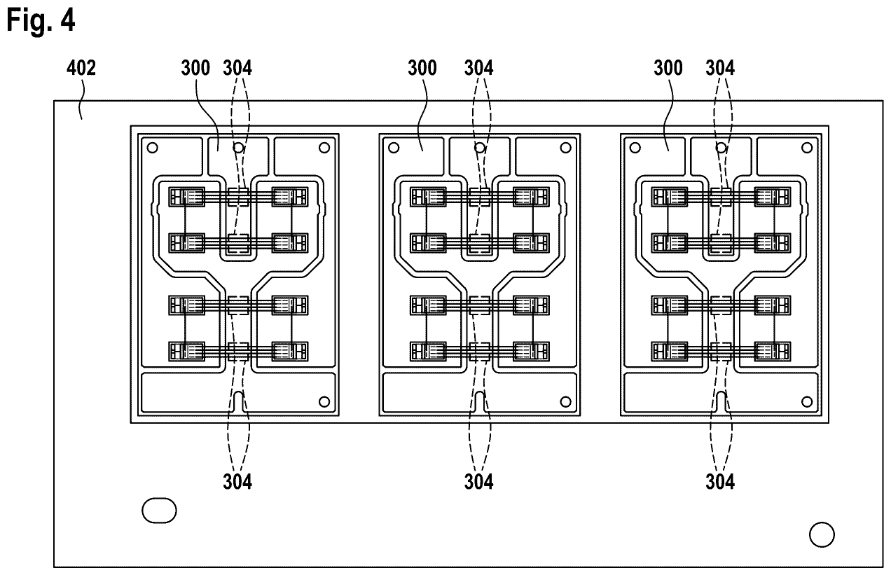

FIG. 4 shows a schematic illustration of three power modules 300 attached to a cooling surface 402. The three power modules 300 are arranged parallel next to one another, so that the fourth conductor structure 107 of the respective power modules 300 points in the same direction. FIG. 4 further shows regions 304 comprising a connection by bonding wires 302 between the semiconductor switches 306 of the conductor structures 104, 106 and 107 on the second conductor structure 105 and the fourth conductor structure 107.

The power modules 300 can be attached to a cooling surface 402 by means of a material-locking connection, such as gluing, for example. Alternatively, the power modules 300 can be attached to the cooling surface 402 by soldering.

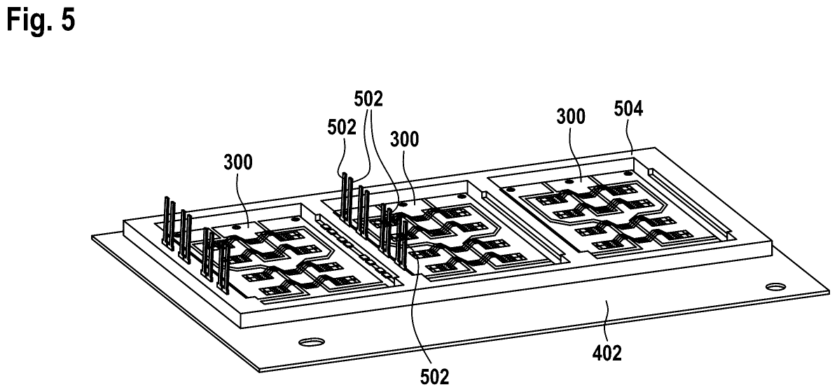

FIG. 5 shows a schematic illustration of three power modules 300 positioned in a frame 504 that is attached to a cooling plate 402. The frame 504 is made of plastic, for example. A frame 504 also includes overmolded press-in pins 502. According to FIG. 5, a frame 504 includes an enclosed volume that is filled with gel.

An enclosed volume can be affected by the dimensions of a frame 504, for example, for instance by determining the length, width and depth dimensions of the power modules 300 to be installed in the frame. A frame 504 in particular has a frame height that exceeds the overall height of a power module 300 and its electronic components, such as bonding wires 302.

A frame 504 can be attached to a cooling surface 402 in any position, for instance, wherein the position can be varied according to the requirements of the respective application, for example in an electric vehicle. A frame 504 is attached to a cooling surface 402 in a material-locking manner, for example.

The assembly variant can be adapted depending on the size and shape of the frame 504, the mechanical stress, the required stability and the assembly process.

The thickness of the frame 504, too, can be varied according to the requirements of the application.

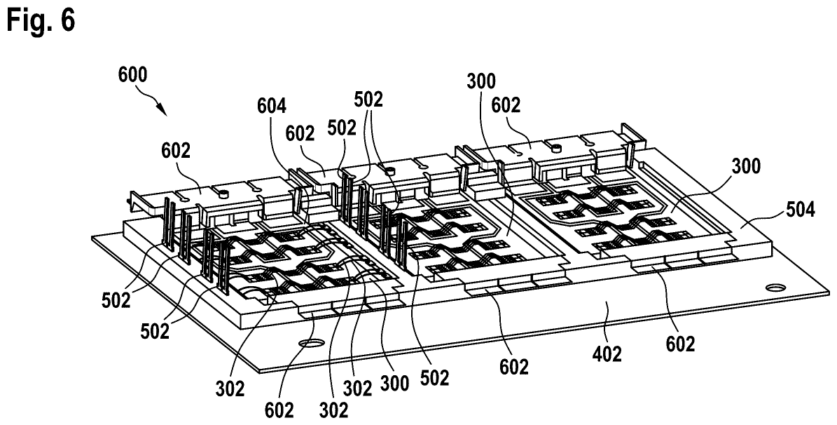

FIG. 6 shows a schematic illustration of a power module bridge 600 with three power modules 300 positioned in a frame 504 and attached to a cooling plate 402. The power module bridge 600 according to FIG. 6 also includes connecting elements 602. The frame 504 is made of plastic, for example. The frame 504 further includes overmolded press-in pins 502. The press-in pins 502 are connected to the semiconductor switches 306 via bonding wires 302. The bonding wires 302 comprise an aluminum material.

According to FIG. 5, the frame 504 includes an enclosed volume that is filled with gel.

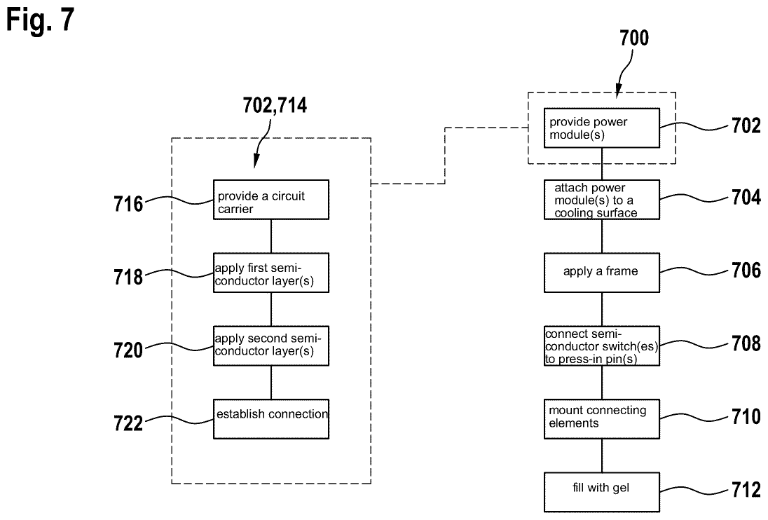

As can be seen from FIG. 7, the shown embodiment example of a method 700 according to the present invention for manufacturing a power module bridge 600 includes six method steps, wherein the method step of providing 702 one or more power modules 300 comprises a sequence of four further steps. A first step is characterized in that providing 702 the one or more power modules 300 is a finishing 714 of a power module. A first step comprises providing 716 a circuit carrier 102. In the second step, the one or more first semiconductor layers 108 are applied 718 to the circuit carrier 102, wherein the application 718 includes bonding by sintering. In the third step, the one or more second semiconductor layers 202 are applied 720 to the first semiconductor layer 108, wherein the application 720 includes bonding by sintering. The last fourth step of finishing 714 includes establishing a connection 722 between the semiconductor switches 306 by means of bonding wires 302.

A method 700 also includes the following steps shown in FIG. 7, starting with providing 702 one or more power modules 300, followed by attaching 704 the one or more power modules 300 to a cooling surface 402, followed by applying 706 a frame 504 including press-in pins 502 to the cooling surface 402 around the one or more power modules 300. The one or more semiconductor switches 306 are then connected 708 to the one or more press-in pins 502 is performed. The method 700 further includes mounting 710 the one or more connecting elements 602 to the one or more power modules 300, wherein the one or more connecting elements 602 are mounted such that each connecting element 602 is secured via the frame 504 and/or to the frame 504, and lastly, a final step comprising filling 712 the enclosed area of the frame 504 with a gel.

Alternatively, a frame 504 can be mounted 706 on the cooling surface 402 before the one or more power modules 300 are attached 704 to a cooling surface 402.

The present invention is not limited to the embodiment examples described here and the aspects highlighted therein. Rather, within the range of the present invention, a large number of modifications are possible which lie within the abilities of a person skilled in the art.

What is claimed is:

1. A power module bridge, comprising:
one or more power modules, wherein each of the one or more power modules includes:
i. one or more circuit carriers which each include at least three layers of material, wherein a middle circuit carrier layer includes an insulating material, a first outer circuit carrier layer and a second outer circuit carrier layer include an electrically conductive material, wherein the first and second outer layers are configured as one or more conductor structures,
ii. one or more bonding wires, wherein the one or more bonding wires include a connection from semiconductor switch to semiconductor switch and semiconductor switch to press-in pins, and
iii. one or more semiconductor switches, wherein each semiconductor switch includes a first semiconductor layer and a second semiconductor layer;
a cooling surface;
a frame with lateral boundaries and with an upwardly and/or downwardly exposed region, wherein a volume enclosed by the frame is filled with a gel;
one or more connecting elements; and
one or more press-in pins;
wherein one or more of the circuit carriers, one or more of the first semiconductor layers, and one or more of the second semiconductor layers are connected to one another via a sintered connection.

2. The power module bridge according to claim 1, wherein the one or more power modules are positioned inside the frame.

3. The power module bridge according to claim 1, wherein at least one of the first outer circuit carrier layers includes one or more conductor structures, wherein the conductor structures are configured such that they have a symmetrical arrangement and/or a shape that is mirrored with respect to a centerline of the circuit carrier layer.

4. The power module bridge according to claim 1, wherein the bonding wires that include a connection from semiconductor switch to semiconductor switch include a copper material.

5. The power module bridge according to claim 1, wherein the bonding wires that include a connection from semiconductor switches to press-in pins include an aluminum material.

6. The power module bridge according to claim 1, wherein the frame has a variable frame height.

7. The power module bridge according to claim 1, wherein the gel in the frame completely covers one or more of the power modules.

8. A method for manufacturing a power module bridge including one or more power modules, a cooling surface, a frame, one or more press-in pins, and one or more connecting elements, each of the power modules including one or more semiconductor switches, wherein each semiconductor switch, the method comprises the following steps:
I. providing the one or more power modules;
II. attaching the one or more power modules to the cooling surface;
III. applying the frame including the press-in pins to the cooling surface around the one or more power modules;
IV. connecting the one or more semiconductor switches to the one or more press-in pins,
V. mounting the one or more connecting elements on the one or more power modules, wherein the one or more connecting elements are mounted such that each connecting element is secured via the frame and/or to the frame, and
VI. filling a region enclosed by the frame with a gel.

9. The method according to claim 8, wherein the one or more power modules are fastened to the cooler via a material-locking connection.

10. The method according to claim 8, wherein the providing of the one or more power modules includes producing each power module, wherein the producing includes the following steps:
providing a circuit carrier,
applying one or more first semiconductor layers to the circuit carrier, wherein the applying of the one or more first semiconductor layers includes bonding by sintering,
applying one or more second semiconductor layers to the one or more first semiconductor layers, wherein the applying of the one or more second semiconductor layers includes bonding by sintering, and
producing a connection between the semiconductor switches using bonding wires.

11. The method according to claim 8, wherein the frame is attached to the cooling surface by gluing or soldering.

12. The method according to claim 8, wherein a signal connection is made via the press-in pins.

13. The power module bridge according to claim 1, wherein the power module bridge is situated in a vehicle and is used to convert current from direct current to alternating current.
